(19) United States
(12) Patent Application Publication
(10) Pub. No.: US 2026/0096397 A1
(43) Pub. Date: Apr. 2, 2026

(54) STEP RAMP GRADING YIELD ENHANCEMENT FOR HYBRID BONDING

(71) Applicant: Tokyo Electron Limited, Tokyo (JP)

(72) Inventors: Partha MUKHOPADHYAY, Oviedo, FL (US); H. Jim FULFORD, Marianna, FL (US)

(21) Appl. No.: 18/902,673

(22) Filed: Sep. 30, 2024

(51) Int. Cl. H01L 23/00; H01L 21/66

(52) U.S. Cl. CPC H10P 74/203; H10W 80/102; H10W 80/312; H10W 80/327

(57) ABSTRACT

Step ramp grading yield enhancement for hybrid bonding is provided. A device may provide a plurality of first contacts on a first substrate. A device may provide a plurality of second contacts on a second substrate, the plurality of second contacts configured to align with the plurality of first contacts. A device may anneal the first substrate and the second substrate to electrically couple the plurality of first contacts to the plurality of second contacts, wherein at least one of an annealing time or an annealing temperature is based on a recess depth of the plurality of first contacts from a surface of the first substrate.

### TECHNICAL FIELD

This disclosure relates to microelectronic devices including semiconductor devices, transistors, and integrated circuits, including methods of microfabrication.

### BACKGROUND

The bonding of layers to form 3D structures is of growing importance in the semiconductor manufacturing industry. For example, semiconductor wafers or reconstituted wafers may be generated with circuit components such as logic, memory and/or passive devices. In order to combine devices in the z-plane, multiple wafers may be bonded together by a bonding process. In some instances, electrical connections are provided on each substrate and connected as part of the bonding process in what is generally termed hybrid bonding. The connections may be provided as copper (Cu) pads and may have a small size and/or pitch (e.g., 5-micron pitch and/or feature size and below). Due to material characteristics and manufacturing challenges, lateral alignment and connection of these fine features can be difficult. Vertical alignment, referring to a recess of contacts (e.g., Cu pillars for the Cu pads) from a substrate surface, may also prove challenging. Recesses may form according to a differing coefficient of expansion relate to the substrate. However, the depth of the recess may further vary over a surface of the substrate due to temperature asymmetries, dishing effects, wafer warpage, and so forth.

### SUMMARY

Described herein are structures and techniques that provide or improve 3D structures and circuits created using hybrid bonding. Abbreviated yield times may avoid certain defects such as excessive dopant or interlayer diffusion, oxide growth, film stress, silicide degradation, or crystallographic defects such as dislocations. However, these annealing times may be insufficient to electrically and mechanically couple at least some corresponding contacts, (e.g., copper contacts, such as copper pillar contacts), as may lead to manufacturing defects, in-service failures, or reduced performance. The techniques described herein improve the yield of bonded technology to reduce anneal times while preserving the connections between the conductive elements.

According to techniques described here, recess depths of various contacts of semiconductor substrates (e.g., wafers, dies, panels, etc.) are measured. An anneal time and temperature (e.g., a ramp profile) to electrically couple the respective contacts of the substrates is determined based on the recess depth. In some embodiment, the ramp profile may further depend on alignment or other factors. The total anneal time includes various dwell times at (e.g., descending temperatures) and ramp rates between the dwell times, either of which may be adjusted according to the recess depths or alignment. In some embodiments, the recess depths are measured across various portions of a substrate to determine an intra-substrate variation (e.g., a peripheral portion and a central portion). The ramp profile may be adjusted according to the variation between the portions, such as according to a damped temperature change exhibited at a center portion of the wafer, relative to the peripheral portions.

In some aspects, the techniques described herein relate to a method including: providing a plurality of first contacts on a first substrate; providing a plurality of second contacts on a second substrate, the plurality of second contacts configured to align with the plurality of first contacts, respectively; and annealing the first substrate and the second substrate to electrically couple the plurality of first contacts to the plurality of second contacts, respectively, wherein at least one of an annealing time or an annealing temperature is based on a recess depth of the plurality of first contacts from a surface of the first substrate.

In some aspects, the techniques described herein relate to a method, wherein the first substrate is a wafer, and further including: selecting the second substrate based on: the recess depth of the plurality of first contacts; and a recess depth of the plurality of second contacts from a surface of the second substrate.

In some aspects, the techniques described herein relate to a method, wherein the second substrate is a panel including a plurality of dies and further including: selecting an arrangement of the plurality of dies based on the recess depth of the plurality of first contacts and the recess depth of the plurality of second contacts.

In some aspects, the techniques described herein relate to a method, wherein the first substrate is a wafer.

In some aspects, the techniques described herein relate to a method, wherein the second substrate is a panel including a plurality of dies.

In some aspects, the techniques described herein relate to a method, wherein the annealing time is based on a variation of the recess depth between a first set of the first contacts disposed at a first portion of the first substrate and a second set of the first contacts disposed at a second portion of the first substrate.

In some aspects, the techniques described herein relate to a method, wherein: the first set of contacts are disposed at a peripheral portion of the first substrate; and the second set of contacts are disposed at a central portion of the first substrate.

In some aspects, the techniques described herein relate to a method, wherein the annealing time includes a plurality of dwell times corresponding to a plurality of the annealing temperatures, the annealing temperatures sequenced according to a descending order.

In some aspects, the techniques described herein relate to a method, wherein the plurality of annealing temperatures are predefined, and lengths of the dwell times or ramp rates between the dwell times are determined according to a measurement of the recess depth of the first substrate and a recess depth of the second substrate.

In some aspects, the techniques described herein relate to a method, wherein the dwell times or the ramp rates are adjusted based on an alignment between the first substrate and the second substrate.

In some aspects, the techniques described herein relate to a method, further including: testing, subsequent to annealing, the first substrate and the second substrate for: an indication of alignment of the plurality of first contacts with the plurality of second contacts; and an indication of a yield of a semiconductor product including the first substrate and the second substrate; ingesting, by a machine learning model trained with alignment data, yield data, ramp rate data, dwell time data, and electrical test data for a plurality of bonded wafers, the indication of alignment and the indication of the yield; executing the machine learning model to generate a prediction of an adjustment to the annealing time or the annealing temperature; and annealing a third substrate including third contacts and a fourth substrate including fourth contacts to electrically couple the third contacts with the fourth contacts according to an adjusted annealing time, adjusted according to the prediction.

In some aspects, the techniques described herein relate to a method, wherein the testing consists of non-destructive testing.

In some aspects, the techniques described herein relate to a method, wherein the testing includes destructive testing.

In some aspects, the techniques described herein relate to a method, wherein the second substrate is a wafer.

In some aspects, the techniques described herein relate to a method including: determining a first recess depth of a plurality of first contacts of a first substrate; determining a second recess depth of a plurality of second contacts of a second substrate; bonding the first substrate to the second substrate to form a bonded structure; and annealing the bonded structure to electrically couple the plurality of first contacts to the plurality of second contacts, wherein an annealing time is based on the first recess depth and the second recess depth.

In some aspects, the techniques described herein relate to a method, further including: determining, a variation between the first recess depths, wherein the annealing time is further based on the variation.

In some aspects, the techniques described herein relate to a method, wherein: the annealing time includes a plurality of dwell times corresponding to a plurality of annealing temperatures; and the determination of the dwell times includes determining the plurality of dwell times.

In some aspects, the techniques described herein relate to a method, wherein a ramp rate between the dwell times is adjusted based on the first recess depth, the second recess depth, and the variation.

In some aspects, the techniques described herein relate to a method, wherein the dwell times are determined based on an alignment between the first substrate and the second substrate.

In some aspects, the techniques described herein relate to a method, wherein the first substrate is a wafer.

In some aspects, the techniques described herein relate to a method, wherein the second substrate includes a cut die.

In some aspects, the techniques described herein relate to a method, further including determining a plurality of dwell times of the annealing time, the determination including: ingesting, by a machine learning model trained with yield data, dwell time data, and electrical test data for a plurality of bonded wafers, the first recess depth and second recess depth; and executing the machine learning model to determine at least one of the plurality of dwell times.

In some aspects, the techniques described herein relate to a method, further including selecting the second substrate based on: the recess depth of the plurality of first contacts; and a recess depth of the plurality of second contacts from a surface of the second substrate, wherein the second substrate includes a cut die.

In some aspects, the techniques described herein relate to a method including: determining a first recess depth of a plurality of first contacts of a first substrate; determining a second recess depth of a plurality of second contacts of a second substrate; determining, a variation between the first recess depths; ingesting, by a machine learning model trained to corelate a first plurality of dwell times with yield data for bonded structures, data including the first recess depth, the second recess depth, and the variation; determining, by the machine learning model based on the ingested data, an annealing time including a second plurality of dwell times; and annealing the first substrate and the second substrate according to the annealing time to electrically couple the plurality of first contacts to the plurality of second contacts.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a pair of substrates to be bonded and electrically connected, in accordance with some embodiments.

FIG. 2 illustrates a cross sectional view of a bonded substrate pair including paired contact structures, in accordance with some embodiments.

FIG. 3 illustrates a ramp curve for an annealing temperature of at least one substrate of a bonded substrate pair, in accordance with some embodiments.

FIG. 4 illustrates a ramp curve for annealing temperatures of separate portions of at least one substrate of a bonded substrate pair, in accordance with some embodiments.

FIG. 5 is a flow chart of a method for making a semiconductor device, in accordance with some embodiments.

FIG. 6 is another flow chart of a method for making a semiconductor device, in accordance with some embodiments.

FIG. 7 depicts an example block diagram of an example computer system, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more semiconductor devices including bonded substrates. The bonds between the substrates can include dielectric bonds relying on Van Der Waals forces and metal-to-metal bonds relying on a coupling of conductive contacts. Generally, the metal-to-metal bonds are emplaced subsequent to the dielectric bonds. For example, the dielectric bonds can be realized according to an interface between planarized surfaces of two substrates, which already include corresponding metal contacts of a metal contact pair. The metal contacts may be somewhat recessed from the planarized surfaces (e.g., a few or several nanometers) and thus may not interfere with the formation of the dielectric bonds. Subsequent to the formation of the hybrid bonds, an anneal operation heats the bonded substrates to expand the volume of the recessed metal contacts, causing the paired metal contacts to expand end eventually meet.

Once the paired metal contacts reach one-another, the respective materials will diffuse across an interface therebetween, and may ultimately recrystallize into grains which eliminate the original interface. In some instances, the respective contacts may merge into a single crystal. Although the diffusion and recrystallization may be accelerated at elevated temperatures, such temperatures can negatively impact other aspects of a semiconductor device. For example, elevated temperatures can lead to excessive dopant or interlayer diffusion, oxide growth, film stress, silicide degradation, or crystallographic defects including dislocations, vacancies, or interstitials of the lattice. Operation, lifespan, and other performance attributes of a semiconductor device (collectively referred to as a yield) thus depends on a recess depth of the contacts, as well as other attributes of a semiconductor device, as may render a particular substrate more or less susceptible to dopant diffusion, silicide degradation, crystallographic defects, or so forth. Recess depths may vary on a substrate-to-substrate basis, as well as over a surface of a substrate (e.g., peripheral recesses on a wafer may be deeper or shallower than centrally located recesses, according to uneven polishing pressures).

Modulating either of an annealing time or an annealing temperature can improve yields of semiconductor devices. Moreover, modulating a total annealing time downwards can reduce energy use, carbon emissions, or machine time. Further, the decreased machine time can, in turn, increase total throughout, or decrease a number or size of annealing chambers (sometimes referred to as ovens or heated chucks) for a given thruput. However, it may be impractical for an operator to determine and adjust a ramp profile under time constraints of semiconductor manufacturing. For example, the total annealing time can include various constituent dwell times corresponding to temperatures. The annealing temperature can include a dwell time or a ramp rate between the temperatures of the individual dwell times.

The ramp profile, including dwell times at various temperatures and ramp rates therebetween, can be determined as based on a recess depth of the wafers. The ramp profile for a subsequent batch may be determined based on the recess depths, as well as test data for a previously annealed batch. Applying received test data, (which can include topographic information of sub-nanometer precision) to a subsequent batch may not be practically performed by a technician, especially so given timelines of semiconductor manufacturing. For example, as performed according to the disclosed systems and methods, total annealing time can be in the tens of minutes (e.g., between ten and fifty minutes), with perhaps thirty minutes of additional test time. Delays between ingesting test data and adjusting the ramp profile may not be practical, since characteristic of semiconductor may change over time, or such delays can lead to repeated thermal cycles (e.g., overcooling a wafer before annealing can compound stress). However, a machine learning model can predict an annealing time or temperature associated with an improved yield, based on past testing data, the recess data, or other substrate characteristics, such as registration data (referred to herein as alignment data).

Although the figures and aspects of the disclosure may show or describe devices herein as having a particular shape, it should be understood that such shapes are merely illustrative and should not be considered limiting to the scope of the techniques described herein. For example, although certain figures show various contacts in a rectangular or cylindrical configuration, other shapes are also contemplated, and indeed the techniques described herein may be implemented in any shape or geometry.

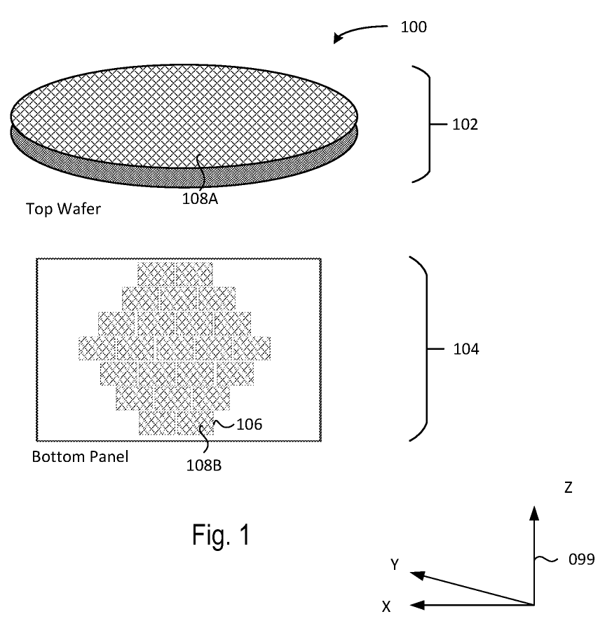

FIG. 1 illustrates a system 100 including a paired set of substrates configured for bonding, such as hybrid bonding. Particularly, the substrates include a top substrate, depicted as a semiconductor wafer 102, and a bottom substrate, depicted as a semiconductor panel 104 including various semiconductor dies 106 configured to interface with the wafer 102. For example, the various semiconductor dies 106 may be diced from one or more further wafers 102.

The depicted substrates are merely an illustrative example and should not be construed as limiting. In some embodiments, the upper and lower substrates are both a semiconductor wafer 102 or both a panel 104 and/or other assemblage of one or more semiconductor dies 106. Moreover, a relative position of one or more substrates may be modified or substituted. Indeed, phrases such as “upper,” “lower,” “right,” or “left” should be construed as describing the provided figures and are not intended to limit the scope of the present disclosure. Various embodiments can orient the various elements described here according to various reference directions.

The top substrate includes first contacts 108A and the bottom substrate includes second contacts 108B. Various instances of the first contacts 108 A or second contacts 108B may be referred to, generally or collectively, as contacts 108. Each substrate includes various contacts 108 of a paired set of contacts 108. The respective contacts 108A, 108B of the respective substrates are configured to interface with each other, such as to stack a memory die over a logic die to form a three-dimensional integrated circuit (3DIC).

A provided axis 110 indicates an x-y plane, which may be referred to as a bonding plane, indicative of an interface between the respective substrates. Movement, distances, etc. which extend along the bonding plane are referred to, herein, as lateral movements, lateral distances, lateral dimensions, etc. A z-direction refers to a direction perpendicular to the bonding plane. Similar language, such as a z-height may also be referred to a device height according to a mounting surface or other substrate (e.g., a printed circuit board). Although such a z-height may generally correspond with the z-direction of the axis 110, such correspondence is not limiting and may, in some embodiments, differ therefrom.

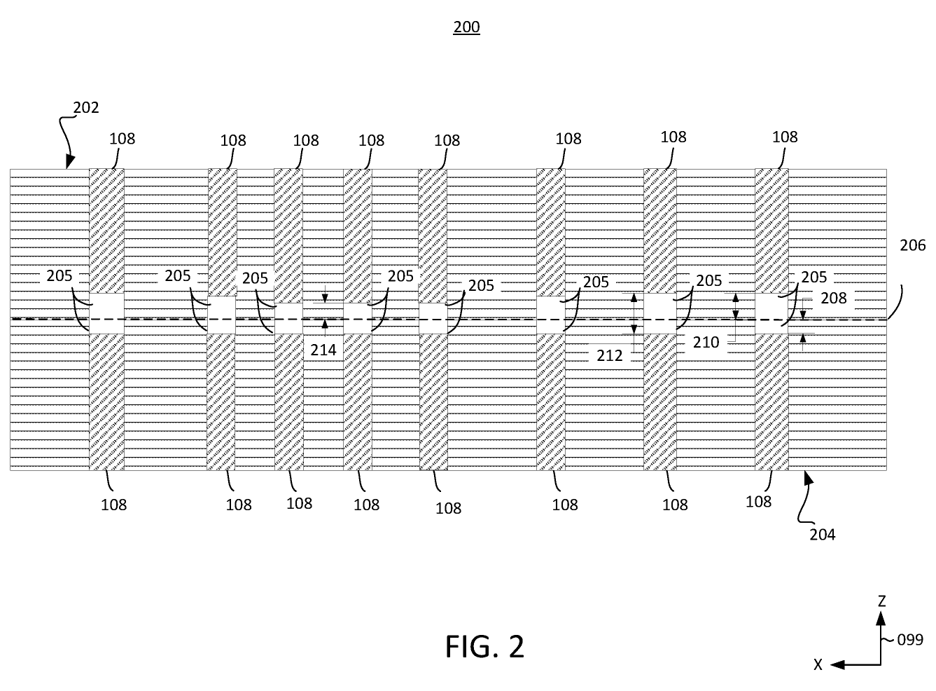

FIG. 2 illustrates a cross sectional view of a semiconductor device 200 including a bonded substrate pair, in accordance with some embodiments. The substate pair includes a top substrate 202 (e.g., a panel 104 or wafer 102, such as the depicted wafer 102 of FIG. 1) and a bottom substrate 204 (e.g., a wafer 102 or panel 104, such as the depicted panel 104 of FIG. 1). A junction of the top substrate 202 and bottom substrate 204 defines a bonding plane 206 which extends laterally upon a generally flat surface of the respective substrates, but which can include vertical variation according to warpage, deviations in thickness, or other attributes of the respective substrates 202, 204.

The depicted condition of the semiconductor device 200 corresponds to a condition of a bonded substrate pair prior to annealing. During an annealing operation, the paired contacts 108 can couple with one-another and occupy the depicted recesses 205. For example, an annealing operation of a bonding process to couple the top substrate 202 with the bottom substrate 204, can apply heat to expand a conductive contact material relative to the substrate material, and maintain the elevated temperature long enough to form an electrical connection (which may also provide mechanical strength in tension upon cooling). Thus, an optimal annealing time can depend on a recess depth (e.g., may include a longer time at a highest temperature leading to the expansion and initial diffusion across the substrate-to-substrate interface).

In some embodiments, a data processing system of the present disclosure can match various substrate pairs according to a combined recess depth. For example, the data processing system can pair various substrates to generate similar recess depths across a population of substrate pairs. The population of substrate pairs can include a single substrate pair, various substrate pairs of a wafer pod basis, or so forth. Likewise, the data processing system can modulate an annealing ramp rate, temperature, dwell time, or other annealing parameter on the per-substrate pair basis, per-pod basis, or so forth. For example, one or more wafers may be deposited in an annealing chamber, and undergo an annealing ramp profile according to an average, minimum, maximum, or other recess depth for the one or more wafers.

In some embodiments, instead of or in addition to an oven-type annealing chamber, a wafer handler including at least one heated chuck may be used to electrically connect the substrate pair. For example, at least one of a top chuck configured to mechanically interface with a first wafer of the wafer pair or a bottom chuck configured to mechanically interface with a second wafer of the wafer pair may be a heated chuck. According to such an approach, a ramp profile (e.g., temperature ramp, dwell temperate, dwell time, etc.) can be modulated on a per-substrate basis or a per-substrate pair basis. For example, higher heat may be applied to a wafer (or wafer pair) associated with a greater recess dimension.

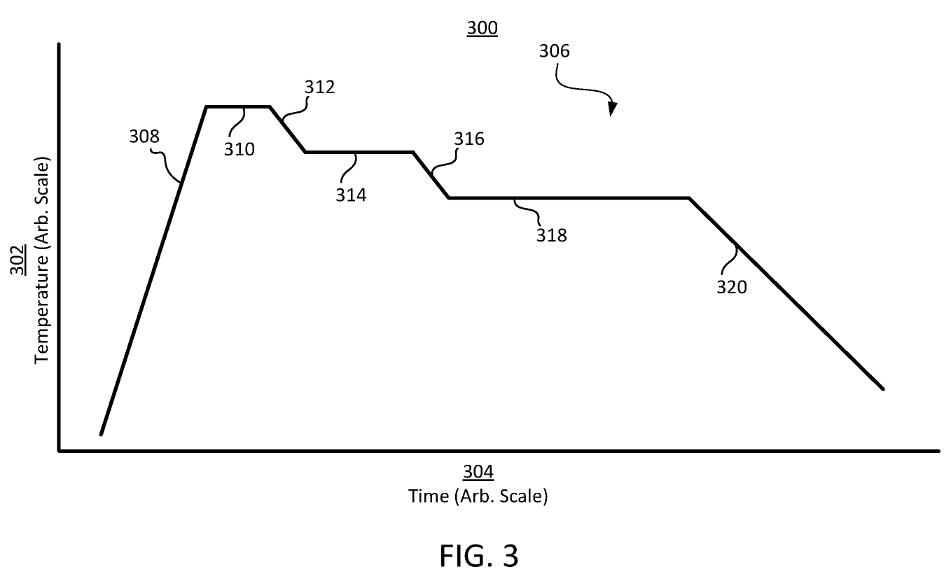

In some instances, the data processing system can include or interface with a zonal heating chuck configured to heat more than one zone of a substrate or substrate pair differently than other zones of the substrate or substrate pair. For example, a zonal heating chuck can include zones defining according to radial portions of a substrate, concentric portions of a substrate, combinations thereof (e.g., a central zone and two or more radial peripheral zones), or according to further geometries. For example, a zonal heated chuck for a generally rectangular panel can include a rectangular grid of heating zones. Where a recess 205 depth varies along a surface of a substrate (an example of which is depicted hereinafter at FIG. 3), the various zones of the substrate can be provided with varying ramp profiles. For example, a ramp rate, dwell temperature, or dwell time may be varied over a surface of a substrate pair so as to provide greater expansion and diffusion time for relatively large recesses 205 and lesser expansion and diffusion time for relatively small recesses 205 (as may correlate positively with other aspects of yields, such as by reducing interlayer diffusion, oxide growth, or film stress).

The depicted recesses 205 may arise from processing prior to bonding the substate pair. For example, the surfaces of the substrate can be planarized according to a chemical-mechanical polishing or grinding (CMP/G). A relatively soft contact 108 of a conductive material (as may consist substantially of or otherwise include copper, gold, or nickel) may be preferentially removed relative to a harder surface of the substrates. For example, as material is removed via mechanical abrasion with a polishing disk or an abrasive slurry, contacts 108 may suffer dishing so as to recess the conductive material from a harder substrate. Some examples of materials of the top substrate 202 and bottom substrate 204 can include mono or polycrystal silicon, silicon germanium, gallium arsenide, silicon carbide, sapphire, or other semiconductor related materials.

In some instances, a recess depth of a contact 108 can owe to chemical processes (e.g., etching) which may be preferential to one of the substrates or the contact 108. Further still, any of the processes can occur at elevated or reduced temperatures, relative to ambient. Accordingly, upon a return to ambient (or an excursion therefrom), a recess depth can increase or decrease according to a difference of a CTE (coefficient of thermal expansion) between the substrate and the conductive material of the contacts 108. Although depicted as substantially level for clarity of the figures, some contacts 108 may exhibit dishing wherein a medial portion of the recess 205 is deeper than a portion bordering the substrate (and may further exhibit non-symmetry corresponding to a rotational direction of a polishing disk or other process). In some embodiments, determinations of a “depth” may refer to a determination of a center point of the recess 205, maximum recessed portion of the contact 108, or another indication of a recessed volume.

A distance between respective contacts 108 of a contact pair include a contribution of each of a pair of recesses 205. For example, referring to the right-most depicted recess 205, a distance between the corresponding contacts 108 is equal to the sum of a first recess depth 208 and a second recess depth 210. Such a combined distance is shown according to a third recess depth 212 with reference to the adjacent contact pair.

Because the metal contacts 108 must expand the distance (e.g., linear distance or volume) of the sum of the pair of recesses 205 to come into contact with one another, annealing times and temperatures will depend on this sum. Thus, although determinations of a depth of one recess 205 may be somewhat predictive of an optimal anneal time or temperature, determinations of each of the pair of recess depths may be provide greater predictive power. In the depicted embodiment, a first recess depth 208 of the bottom substrate 204 is provided without variation over the depicted lateral portion of the bottom substrate 204. Conversely, recess depths of the top substrate 202 vary along the depicted view. Particularly, the recesses 205 of a central portion of the top substrate 202 exhibit less depth than recesses 205 of a central portion. For example, a second recess depth 210 of a peripheral recess 205 is shown as exceeding a fourth recess depth 214 of a centrally located recess 205. In general, recess depths may vary across various substrate portions. For example, a center-mount chuck used in planarization may lead to greater dishing (and recess depth) in a central portion of a wafer, while other techniques may lead to greater recess depths in a peripheral portion of the semiconductor device 200 (as is depicted).

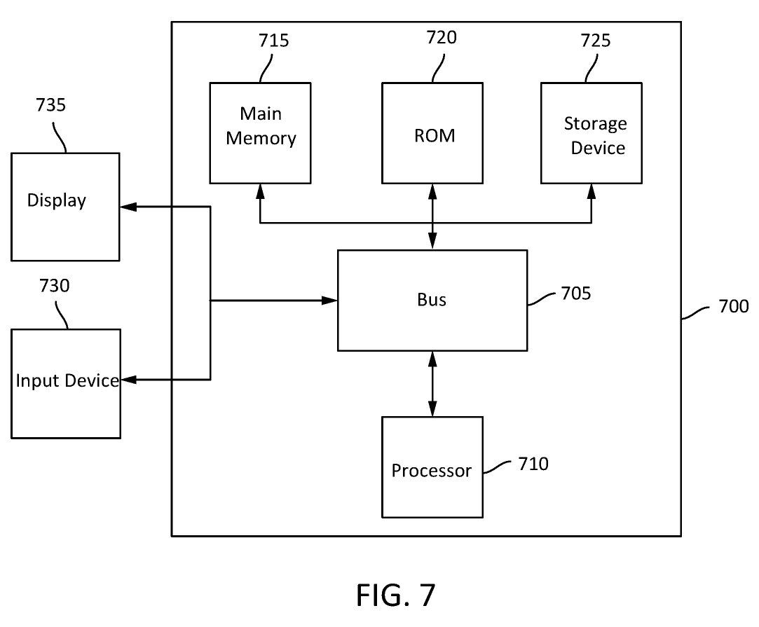

In some embodiments, substrates are matched according to a recess depth of corresponding portions. For example, a controller (e.g., the computer system of FIG. 7) can match a first wafer 102 exhibiting greatest recess depths in a central portion with another wafer exhibiting greatest recess depths in a peripheral portion. Similarly, the controller can determine a position for individual dies 106 of a panel 104 to offset differences between recess depths of matching pairs, when coupled with a wafer 102 or other substrate. Such matching may reduce a combined distance between recess depths, and may, in turn, reduce a total time annealing time, or a time at an elevated temperature (e.g., a first dwell time of FIG. 3).

In some instances, the contacts 108 of the top substrate 202 may be laterally offset from corresponding contacts 108 of the bottom substrate 204. A resultant misalignment between the contacts 108 can increase a resistance of a connection formed between the corresponding contacts, and may also decrease a mechanical strength of the connection. Misalignment between contacts 108 occurs for a variety of reasons such as material expansion caused by temperature or CTE (coefficient of thermal expansion) mismatch, stretch or shift along a bond interface that may occur as the bonding interface is created and propagates across the substrate, warpage of either substrate, particle interference at the bond interface, or other sources of misalignment. Moreover, the alignment may vary across various portions of the respective substrates. In some instances, processes to correct or mitigate misalignment may be performed such as thermal reflow or alignment re-work. However, such techniques may not always be practical, or may not fully resolve alignment issues.

Increasing dwell times of a ramp rate may aid in forming electrical and mechanical connections between contacts 108 of corresponding substrates. For example, extending a highest temperature may be particularly useful for expanding contacts of deep recesses or forming robust mechanical connections for misaligned contacts. However, it may be difficult to balance the benefits realized by the contact against any harm incurred by other components of the semiconductor device 200. For example, to bond a particular contact pair with a total recess depth of fifteen nm and offset by one nm, it is not intuitive whether providing substantial time at a relatively low temperature (e.g., twenty minutes at 300° C) or less time at a relatively high temperature (e.g., eight minutes at 350° C) would provide a better overall yield. Indeed, it might be better to provide no additional time, in some instances (e.g., where dopant diffusion between a source and gate is already marginal). Further, a semiconductor device 200 can include hundreds or thousands of contacts, each having a separate alignment and recess depth.

A machine learning model can correlate received measurements of recess depths, alignments, or other attributes of the semiconductor device 200 to predict or determine a yield. For example, the machine learning model may ingest, as a part of a training operation, alignment data, yield data, ramp profile data (including temperatures, dwell times, ramp rates, etc.), and electrical test data for many bonded wafers to determine optimal values of a ramp profile. In some embodiments, the machine learning model is trained, according to ingested data, to corelate dwell times with yield data for bonded structures. The ingested data can include recess depths and variation across a substrate. Accordingly, the machine learning model can predict a yield (or optimal ramp profile) based on measured recess depths of a bonded substrate. The machine learning model may be operatively coupled with an annealer over to execute a ramp curve based on the prediction or determination.

According to various embodiments, the machine learning model can include various architectures as may determine multi-variable regression for a local minimum of an optimal value, or classification models, to classify a wafer with a cluster or other set of wafers having known yield data. The values determined by the machine learning model of the present disclosure should be understood to refer to a local optimum (e.g., a local minimum of a cost function). This optimum may differ from a global optimum according to limitations of the model or potential traps.

According to the various embodiments contemplated according to the present disclosure, the machine learning model can operate on datasets for any number of substrates. For example, the machine learning model can predict, for a zonal chuck, a yield or annealing parameters associated therewith on a zone basis, substrate basis or other population basis. For a batch process, the machine learning model can predict a yield, or annealing parameters associated therewith on a substrate basis or other population basis (e.g., pod or other collection of substrates).

Referring further to the testing of the semiconductor device 200, testing can include various destructive or non-destructive methods. For example, a daisy chain structure of contacts 108 can be formed according to the electrical coupling between the top substrate 202 and bottom substrate 204. Testing of the daisy chain structure can include measuring a continuity, electrical or thermal resistance, inductance, transmission line characteristic, or other aspect of the daisy chain structure. In some cases, all (or a sample) of semiconductor devices 200 can, pre- or post-annealing, undergo destructive testing such as SEM imaging of cut portions, blade tests for bond energy, or so forth. In some embodiments, the testing can include an end-of-line functional test.

FIG. 3 illustrates a graph 300 of a ramp profile 306 for an annealing time and temperature of at least one substrate of a bonded substrate pair, in accordance with some embodiments. The ramp profile 306 is provided according to a temperature axis 302 and time axis 304. The depicted temperatures can refer to either of a chamber temperate of a chamber including the bonded substrate pair, or a surface or other temperature of at least one substrate of the bonded pair. In some embodiments, the temperature corresponds to an average temperature, maximum temperature, or a temperature of a particular portion of a substrate (e.g., central portion, peripheral portion, or other portion).

A first segment of the ramp profile curve 306 corresponds to a first ramp rate 308 between an ambient or other initial temperature and a first dwell time 310 at a first temperature. In some embodiments, the first ramp rate 308 may be provided as a maximum of the annealing chamber. In some embodiments, the first ramp rate 308 may be less than the maximum ramp rate. The temperature of the first dwell time 310 may exceed typical annealing temperatures. For example, in some embodiments, the temperature equals or exceeds 400° C for copper contacts. In some embodiments, the temperature of the first dwell time 310 is the greatest temperature of the ramp profile curve 306. For example, the various temperatures of the ramp profile curve 306 may be arranged as sequenced according to a descending order from the highest temperature to the lowest temperature. That is, the ramp profile curve 306 can monotonically decrease subsequent to the first ramp rate 308.

Any of the first ramp rate 308, or the of the first dwell time 310 (e.g., a time and temperature thereof) may be selected according to execution the machine learning model. In some embodiments, some aspects of the first ramp rate 308, or the dwell time 310 are predefined. For example, in some embodiments, the value of the temperature of the first dwell time 310 (or further temperatures) is predefined, and the machine learning model can determine or predict various of the dwell times 310, 314, 318 of the ramp profile curve 306. Such a machine learning model may be trained on alignment data, yield data, ramp rate data, dwell time data, and electrical test data for a plurality of bonded wafers. Further, such values may be determined according to any of misalignment data, recess depth data, or variation of such data over various portions of at least one substrate (e.g., a bonded substrate pair).

Subsequent to the first dwell time 310 at the first temperature, a controller coupled with a chamber (e.g., the computer system 700 of FIG. 7) can adjust the temperature of an annealing chamber environment or the substrate therein along a second ramp rate 312 (e.g., a negative ramp rate) to a second temperature of a second dwell time 314, and a third ramp rate 316 (e.g., another negative ramp rate) to a third temperature of a third dwell time 318. In some embodiments, the additional or fewer ramp rates and dwell times may be included in a particular ramp profile curve 306. For example, as depicted, a further ramp rate 320 may be provided to continue grain growth while returning the bonded wafers to ambient or near ambient conditions, such as about 100° C, or another temperature exhibiting limited grain growth of coupled metal contact pairs. In some embodiments, separate dwell times may be associated with different phases of metal-to-metal bonding. For example, at least the first temperature of the first dwell time 310 (or a duration of at least a portion of the first ramp rate 308 time and second ramp rate 312) may be associated with metal expansion, bringing the respective contacts into contact with one another. At least one subsequent duration of a ramp rate or annealing time may be associated with diffusion or grain growth. Such associations may be provided explicitly in a machine learning model (e.g., according to an eXplainable AI model) or otherwise provided according to, for example, weightings between hidden layers of a neural network.

In some instances, realized yields may vary somewhat from a prediction of the machine learning model. For example, sensor inaccuracy, variation between commanded and realized outputs (e.g., setpoint error of an annealing chamber), and spatial gradients or other variations within an annealing chamber can contribute to error. Further, more systemic manufacturing issues and bias within the model itself can contribute to an error function describing a deviation between predicted and realized results. However, the data processing system of the present disclosure can implement feedback control (e.g., using backpropagation or other techniques) to reduce the error function over time. Such an approach may account for various parameters, even when they may not be explicitly ingested by the model (e.g., variance in quality of a semiconductive ingots, seasonal variation in temperature control, or so forth). In this feedback loop, the error function quantifies the discrepancy between the predicted and realized yields. For example, the data processing system can calculate the difference between predicted and realized values (e.g., using metrics such as Mean Squared Error, MSE or Mean Absolute Error, MAE). As the machine learning model iteratively implements adjustments responsive to such feedback, it can refine an ability to predict wafer yields more accurately, as well as modulation parameters to realize such improved yields (e.g., the dwell times, dwell temperatures, and ramp rates of the ramp profile curve 306).

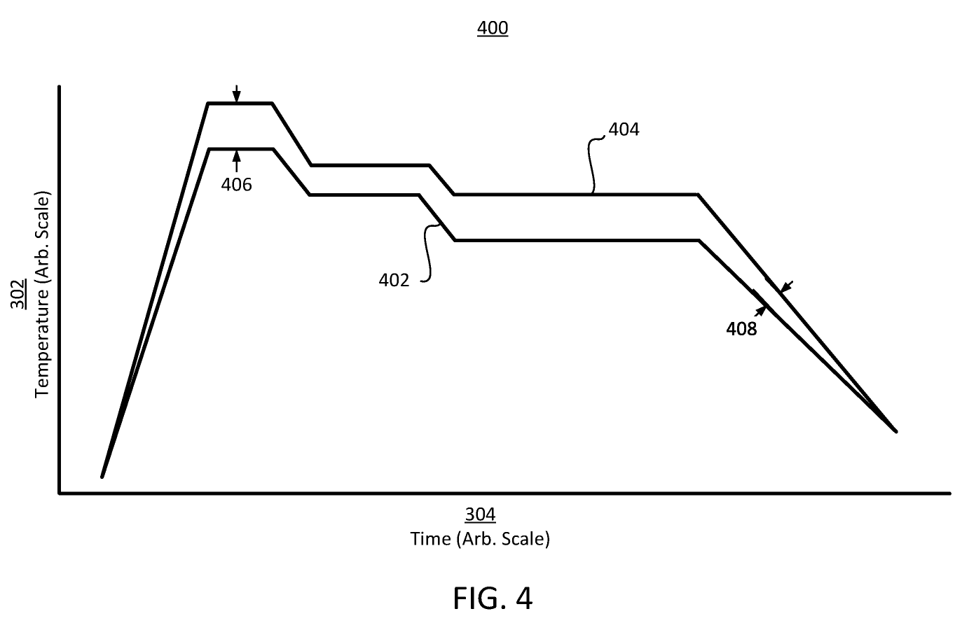

FIG. 4 illustrates a graph 400 of ramp profile curves for annealing temperatures of separate portions of at least one substrate of a bonded substrate pair, in accordance with some embodiments. For example, a first 402 of the ramp profile curves can correspond to a central portion of the bonded substrate pair while a second 404 of the ramp profile curves can correspond to a peripheral portion of the bonded substrate pair. The temperature of the central portion lags the outer portion according to a thermal mass of the substrate, wherein thermal diffusion from peripheral portions to the central portion is somewhat delayed. Further, in some embodiments, upper and lower surfaces (or other portions) of the bonded pair may exhibit different ramp profile curves. For example, where an upper or lower surface is in contact with another thermal mass, or is exposed to a radiative thermal source, the temperature of a particular portion may vary. The variance can include leading or lagging temperatures which converge towards a same temperature, or a persistent offset between portions of the bonded substrate pair. For example, a first offset 406 depicts a persistent offset during a dwell time, while a second offset 408 is convergent.

The ramp profile curves can correspond to a measured or modeled value. For example, the temperature profiles of various portions of the bonded substrate pair may be characterized by the machine learning model or an input thereto. In some embodiments, further ramp profile curves can correspond to further portions of a substrate, such as an upper and lower substrate of the bonded pair, individual dies of a panel (e.g., the dies 106 of the panel 104 of FIG. 1), radial zones of a wafer (e.g., the wafer 102 of FIG. 1), or so forth.

In some embodiments, the machine learning model or other aspect of a controller is configured to determine a net yield based on the temperature variations across the various portions of the bonded substrate pair, as based on temperature ramp profile curves corresponding to different portions of a substrate. For example, a model can predict a first yield for a first portion according to a first temperature ramp profile curve, a second yield for a second portion according to a second temperature ramp profile curve, and a third yield (e.g., net yield) based on the first yield and the second yield.

In some embodiments, the machine learning model can determine a ramp profile curve (or an adjustment thereto) according to a persistent or convergent offset. For example, where a recess depth of a central portion is less than a recess depth of a peripheral portion, the model can determine that a chamber temperature (e.g., 400° C) can heat the central portion to about 400° C, and the outer portion to about 420° C, as may be useful to electrically (or mechanically) couple the corresponding contacts of each portion, without diminishing a net yield.

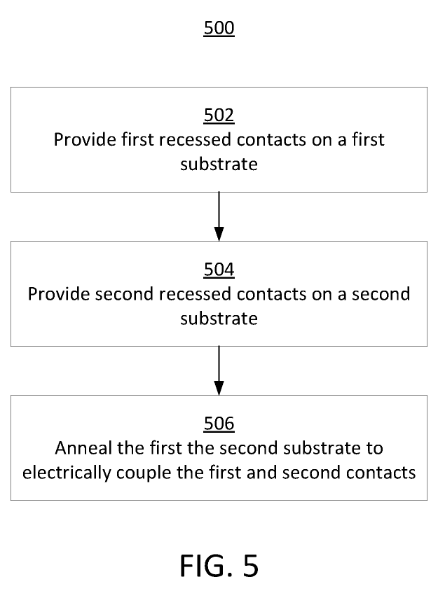

FIG. 5 is a flow chart of a method 500 for making a semiconductor device, in accordance with some embodiments. At least some operations of the method 500 may be performed according to instructions of a controller, such as a controller implementing a machine learning model of a data processing system. In brief overview, the method 500 starts with operation 502 of providing first contacts on a first substrate. The method 500 continues to operation 504 of providing second contacts on a second substrate configured to align with the first contacts. The method 500 proceeds to operation 506 of annealing the first substrate and the second substrate to electrically couple the first contacts to the second contacts. According to some embodiments, the provided operations of this method 500 may be omitted, added, substituted, or otherwise modified.

Referring again to operations 502 and 504, first and second substrates are provided. Each of the first and second substrates can include (e.g., be impregnated with) corresponding first and second contacts (e.g., corresponding to the first contacts 108A and second contacts 108B of FIG. 1 or FIG. 2). The second contacts are configured to align with the first contacts. For example, the respective contacts can consist of or otherwise include a same conductive material (e.g., copper).

Each of the first and second substrates may be provided as wafers, dies (including panels thereof), individual components, or pre-assembled submodules (e.g., the substrates themselves can include a stack of constituent substrates). The contacts of the first and second substates are provided recessed from surfaces of the respective substrates. The method 500 can include measuring or otherwise receiving an indication of a depth of the recesses of at least one of the substrates. In some embodiments, an indication of the depth of a recess of both of the substrates is received. In some embodiments, an indication of the depth of a substrate for various portions of a substrate is received (e.g., inner and peripheral portions, separate dies, radial sections, or other zones). According to various embodiments, the indication of the recessed depth may be determined on a contact-basis (for every contact), a portion basis (for every relevant), a substrate basis (e.g., for every wafer, panel, or die), or on a batch basis (e.g., for a set of substates).

The recessed depth may be determined according to atomic force microscopy (AFM), critical dimension scanning electron microscopy (CD-SEM), X-ray reflectometry (XRR), ellipsometry, or other techniques. In some embodiments, the recessed depth may be determined in conjunction with a wafer topography process such as an interferometric or profilometric process. In some embodiments, the first substrate or the second substrate is selected according to the measured recess depth. For example, substrates may be selected to match recess depths or based on a combined recess depth. In some embodiments, dies of a panel or other substrates may be selected, arranged, or otherwise manipulated based on recess depths of aligned contacts.

The first and second substrates may be provided separately, or as a bonded pair. For example, the first and second substrates may be provided as bonded according to a dielectric bond. In some embodiments, the method includes bonding the first and second substrates to form the bonded substrate pair.

Referring again to operation 506, the first and second substrates are annealed to electrically couple the first contacts with the second contacts. An annealing time (e.g., a dwell time at a temperature) or an annealing temperature (e.g., a ramp rate between the temperatures) of the annealing is based on a recess depth of the first contacts and may further be based on a recess depth of the second contacts, or a variation of either of the first or second contacts. For example, the annealing time or temperature can be based on a subset of the first contacts or the second contacts disposed in a portion of a respective substrate, such as a central or peripheral portion of a wafer, or a die location on a panel. In some embodiments, the annealing time includes multiple dwell times at temperatures sequenced according to a descending order. For example, the temperatures of the dwell times may be predefined, wherein the determination of the length of the dwell times, or ramp rates therebetween, are determined according to the recess depths of the bonded substrates, or alignment data of the respective substrates.

In some embodiments, the method includes testing the bonded wafer pair subsequent to the annealing of operation 506. For example, the testing can determine an indication of alignment of the first contacts with the second contacts (including variation of the recess depth or alignment along the substrate). The testing can further determine an indication of a yield of a semiconductor product including the bonded substrates. For example, the testing can determine a functionality, performance metric, or other aspect of a yield. Such testing can include destructive or non-destructive testing, in various embodiments. The alignment data or yield data of the testing may be ingested by a machine learning model. For example, such data may be used to train the model in a first instance, or be ingested to determine a classification of a substrate according to the model. For example, the machine learning model can predict an adjustment to the annealing time or the annealing temperature for a subsequent annealing operation of further substrates (e.g., a third and fourth substrate). In some embodiments, the method 500 includes annealing a further substrate pair. One of the pair includes third contacts; another of the pair includes fourth contacts configured to electrically couple with the third contacts. This subsequent annealing operation may be performed according to an adjusted annealing time, adjusted according to the prediction of the machine learning model.

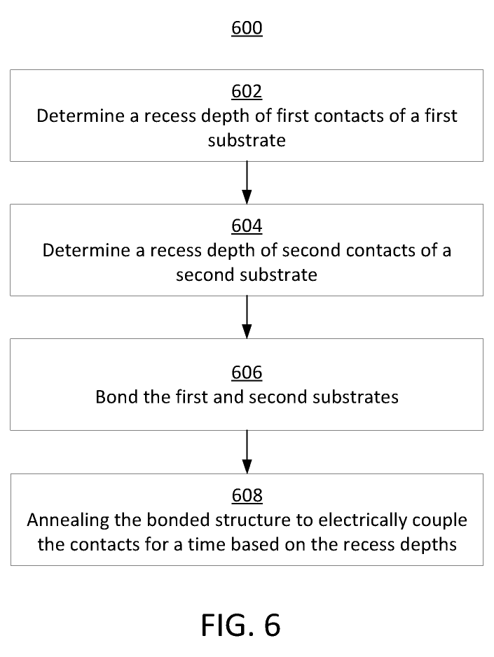

FIG. 6 is another flow chart of a method 600 for making a semiconductor device, in accordance with some embodiments. At least some operations of the method 600 may be performed according to instructions of a controller, such as a controller implementing a machine learning model of a data processing system. In brief overview, the method 600 starts with operation 602 of determining a recess depth of first contacts of a first substrate. The method 600 continues to operation 604 determining a recess depth of second contacts of a second substrate. The method 600 proceeds to operation 606 of bonding the first and second contacts. The method 600 proceeds to operation 608 of annealing, for a time based on the recess depth, the bonded structure to electrically couple the contacts. According to some embodiments, the provided operations of this method 600 may be omitted, added, substituted, or otherwise modified.

Referring again to operations 602 and 604, the method 600 includes determining first recess depths of first contacts of a first substrate, and second recess depths of second contacts of a second substrate. The determination can include testing, such as may be performed according to the present disclosure or otherwise, or other receipt of indications of depth information for the various contacts. As described with regard to the method 500 of FIG. 5, either of the first substrate or the second substrate can include a wafer, cut die(s), or other sub-modules or devices.

Referring again to operation 606, the first and second substrates are bonded. For example, the substrates may be bonded according to a dielectric bond (sometimes referred to as an initial or primary bond, and sometimes preceded by another initial or primary bond, such as an adhesive bond). In some embodiments, prior to one or more bonding sub-operations of operation 606, the wafer is tested, such as to determine variation between recess depths, or an inter-wafer alignment.

Referring again to operation 608, the bonded structure is annealed to electrically couple the first contacts with the second contacts. An annealing time of operation 608 may vary according to at least the first and second recess depths determined at operations 602 and 604 of the present method 600. In some embodiments, the annealing time may further depend upon a variation between any of the first recess depths, second recess depths, or a combination thereof (e.g., a sum thereof). For example, the references to the anneal time can include multiple dwell times, each corresponding to an anneal temperature. Further, in some embodiments, ramp rates between dwell time temperatures may depend on the recess depths, variation thereof, misalignments, or other aspects of the substrates.

FIG. 7 depicts an example block diagram of an example computer system 700. The computer system or computing device 700 can include or be used to implement a data processing system or its components. The data processing system can instantiate, train store, and execute a machine learning model of the present disclosure. The computing system 700 includes at least one bus 705 or other communication component for communicating information and at least one processor 710 or processing circuit coupled to the bus 705 for processing information. The computing system 700 can also include one or more processors 710 or processing circuits coupled to the bus for processing information. The computing system 700 also includes at least one main memory 715, such as a random-access memory (RAM) or other dynamic storage device, coupled to the bus 705 for storing information, and instructions to be executed by the processor 710. The main memory 715 can be used for storing information during execution of instructions by the processor 710. The computing system 700 may further include at least one read only memory (ROM) 720 or other static storage device coupled to the bus 705 for storing static information and instructions for the processor 710. A storage device 725, such as a solid-state device, magnetic disk or optical disk, can be coupled to the bus 705 to persistently store information and instructions.

The computing system 700 may be coupled via the bus 705 to a display 735, such as a liquid crystal display, or active-matrix display, for displaying information to a user such as a user disposed within a semiconductor fabrication facility or exterior thereto. An input device 730, such as a button or voice interface may be coupled to the bus 705 for communicating information and commands to the processor 710. The input device 730 can include a touch screen display 735. The input device 730 can also include a cursor control, such as a mouse, a trackball, or cursor direction keys, for communicating direction information and command selections to the processor 710 and for controlling cursor movement on the display 735.

The processes, systems and methods described herein can be implemented by the computing system 700 in response to the processor 710 executing an arrangement of instructions contained in main memory 715. Such instructions can be read into main memory 715 from another computer-readable medium, such as the storage device 725. Execution of the arrangement of instructions contained in main memory 715 causes the computing system 700 to perform the illustrative processes described herein. One or more processors in a multi-processing arrangement may also be employed to execute the instructions contained in main memory 715. Hard-wired circuitry can be used in place of or in combination with software instructions together with the systems and methods described herein. Systems and methods described herein are not limited to any specific combination of hardware circuitry and software.

Although an example computing system has been described in FIG. 7, the subject matter including the operations described in this specification can be implemented in other types of digital electronic circuitry, or in computer software, firmware, or hardware, including the structures disclosed in this specification and their structural equivalents, or in combinations of one or more of them.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method comprising:
providing a plurality of first contacts on a first substrate;
providing a plurality of second contacts on a second substrate, the plurality of second contacts configured to align with the plurality of first contacts, respectively; and
annealing the first substrate and the second substrate to electrically couple the plurality of first contacts to the plurality of second contacts, respectively,
wherein at least one of an annealing time or an annealing temperature is based on a recess depth of the plurality of first contacts from a surface of the first substrate.

2. The method of claim 1, wherein the first substrate is a wafer, and further comprising:
selecting the second substrate based on:
the recess depth of the plurality of first contacts; and
a recess depth of the plurality of second contacts from a surface of the second substrate.

3. The method of claim 2, wherein the second substrate is a panel comprising a plurality of dies and further comprising:
selecting an arrangement of the plurality of dies based on the recess depth of the plurality of first contacts and the recess depth of the plurality of second contacts.

4. The method of claim 1, wherein the annealing time is based on a variation of the recess depth between a first set of the first contacts disposed at a first portion of the first substrate and a second set of the first contacts disposed at a second portion of the first substrate.

5. The method of claim 4, wherein:
the first set of contacts are disposed at a peripheral portion of the first substrate; and
the second set of contacts are disposed at a central portion of the first substrate.

6. The method of claim 1, wherein the annealing time comprises a plurality of dwell times corresponding to a plurality of the annealing temperatures, the annealing temperatures sequenced according to a descending order.

7. The method of claim 6, wherein the plurality of the annealing temperatures are predefined, and lengths of the dwell times or ramp rates between the dwell times are determined according to a measurement of the recess depth of the first substrate and a recess depth of the second substrate.

8. The method of claim 7, wherein the dwell times or the ramp rates are adjusted based on an alignment between the first substrate and the second substrate.

9. The method of claim 1, further comprising:
testing, subsequent to annealing, the first substrate and the second substrate for:
an indication of alignment of the plurality of first contacts with the plurality of second contacts; and
an indication of a yield of a semiconductor product comprising the first substrate and the second substrate;
ingesting, by a machine learning model trained with alignment data, yield data, ramp profile curve data, and electrical test data for a plurality of bonded wafers, the indication of alignment and the indication of the yield;
executing the machine learning model to generate a prediction of an adjustment to the annealing time or the annealing temperature; and
annealing a third substrate comprising third contacts and a fourth substrate comprising fourth contacts to electrically couple the third contacts with the fourth contacts according to an adjusted annealing time, adjusted according to the prediction.

10. The method of claim 9, wherein the testing consists of non-destructive testing.

11. The method of claim 9, wherein the testing comprises destructive testing.

12. The method of claim 1, further comprising:
bonding the first substrate to the second substrate prior to annealing the respective substrates.

13. A method comprising:
determining a first recess depth of a plurality of first contacts of a first substrate;
determining a second recess depth of a plurality of second contacts of a second substrate;
bonding the first substrate to the second substrate to form a bonded structure; and
annealing the bonded structure to electrically couple the plurality of first contacts to the plurality of second contacts, wherein an annealing time is based on the first recess depth and the second recess depth.

14. The method of claim 13, further comprising:
determining, a variation between the first recess depths, wherein the annealing time is further based on the variation.

15. The method of claim 14, wherein:
the annealing time comprises a plurality of dwell times corresponding to a plurality of annealing temperatures; and
the determination of the annealing time comprises determining a duration of the plurality of dwell times.

16. The method of claim 14 wherein a ramp rate between the dwell times is adjusted based on the first recess depth, the second recess depth, and the variation.

17. The method of claim 13 wherein the dwell times are determined based on an alignment between the first substrate and the second substrate.

18. The method of claim 13, further comprising determining a plurality of dwell times of the annealing time, the determination comprising:
ingesting, by a machine learning model trained with yield data, dwell time data, and electrical test data for a plurality of bonded wafers, the first recess depth and the second recess depth; and
executing the machine learning model to determine at least one of the plurality of dwell times.

19. The method of claim 13, further comprising selecting the second substrate based on:
the recess depth of the plurality of first contacts; and
a recess depth of the plurality of second contacts from a surface of the second substrate,
wherein the second substrate comprises a cut die.

20. A method comprising:
determining a first recess depth of a plurality of first contacts of a first substrate;
determining a second recess depth of a plurality of second contacts of a second substrate;
determining, a variation between the first recess depths;
ingesting, by a machine learning model trained to corelate a first plurality of dwell times with yield data for bonded structures, data comprising the first recess depth, the second recess depth, and the variation;
determining, by the machine learning model based on the ingested data, an annealing time comprising a second plurality of dwell times; and
annealing the first substrate and the second substrate according to the annealing time to electrically couple the plurality of first contacts to the plurality of second contacts.
